(19) United States
(12) Patent Application Publication
(10) Pub. No.: US 2026/0293075 A1
(43) Pub. Date: Sep. 24, 2026

(54) TAPE FEEDER

(71) Applicant: FUJI CORPORATION, Chiryu (JP)

(72) Inventors: Kenichi HAYASHI, Ichinomiya-shi (JP); Akiyoshi MIURA, Chiryu-shi (JP)

(73) Assignee: FUJI CORPORATION, Chiryu (JP)

(21) Appl. No.: 19/473,819

(22) PCT Filed: May 24, 2023
(86) PCT No.: PCT/JP2023/019288

§ 371 Date: Oct. 9, 2025

(51) Int. Cl. H05K 13/04; H05K 13/02

(52) U.S. Cl. CPC H05K 13/0419; H05K 13/021

(57) ABSTRACT

A tape feeder includes a tape guide to guide a carrier including a base tape and a cover tape bonded to the base tape with adhesive sections extending in a tape length direction and covers a cavity; a tape feeding mechanism to feed the carrier tape; a tape peeling mechanism to peel a first side edge of the cover tape from the base tape together with one of the adhesive sections to open the cavity; and a first passage that is provided in the tape guide and through which the peeled first side edge of the cover tape is fed, and a second passage below the first passage and has a passage width dimension equal to or larger than a passage width dimension of the first passage and through which the peeled first side edge of the cover tape is returned in the reverse direction.

### TECHNICAL FIELD

The present description relates to a tape feeder that supplies a component using a carrier tape.

### BACKGROUND ART

A technique for mass-producing board products by performing board work on a board on which a circuit pattern is formed is widespread. A typical example of a board work machine for performing the board work is a component mounter that mounts a component on a board. In general, the component mounter includes a tape feeder that supplies a component using a carrier tape. There are multiple models of tape feeders, and for example, there is a model that includes a tape peeling mechanism that peels a first side edge of a cover tape from a base tape constituting a carrier tape and supplies a component in a half-peeled state in which a second side edge of the cover tape is bonded. One technical example related to this type of tape feeder is disclosed in Patent Literature 1.

Patent Literature 1 discloses an automatic loading feeder including a recovery functional section that determines whether separation has been started before a suction nozzle starts a pickup operation after a tip end of a carrier tape is fed to a tape peeling blade, and performs, when it is determined that the separation has not been started, a recovery operation of temporarily returning the tip end of the carrier tape to a position before the tape peeling blade and feeding the carrier tape again. According to this, it is possible to quickly determine whether peeling has started.

### CITATION LIST

### Patent Literature

Patent Literature 1: WO 2016/147339

### BRIEF SUMMARY

### Technical Problem

Meanwhile, in the technical example of Patent Literature 1, there is a concern that damage such as wrinkles, tearing, and irregular slack occurs in the cover tape so that a subsequent component supply operation is hindered when the carrier tape is repeatedly fed and returned in the recovery operation. This concern is not limited to the recovery operation when the tip end of the carrier tape is peeled off, and may occur in the carrier tape in use. Furthermore, this concern is common to models that supply components in the half-peeled state of the cover tape in addition to the automatic loading feeder.

Therefore, an object of the present description is to provide a tape feeder capable of reducing stress acting on the cover tape returned in a reverse direction and reducing damage to the cover tape.

### Solution to Problem

The present description discloses a tape feeder including: a tape guide configured to guide a carrier tape in a predetermined feeding direction, the carrier tape including a base tape provided with a cavity configured to accommodate a component and a cover tape that is bonded to the base tape with two adhesive sections extending in a tape length direction and covers the cavity; a tape feeding mechanism configured to feed the carrier tape in the feeding direction along the tape guide and return the carrier tape in a reverse direction; a tape peeling mechanism configured to peel first side edge of the cover tape from the base tape together with one of the adhesive sections to open the cavity when the carrier tape is fed in the feeding direction; and a first passage that is provided in the tape guide and through which the peeled first side edge of the cover tape is fed in the feeding direction, and a second passage that is located below the first passage and has a passage width dimension equal to or larger than a passage width dimension of the first passage and through which the peeled first side edge of the cover tape is returned in the reverse direction.

In addition, the present description discloses a tape feeder including: a tape guide configured to guide a carrier tape in a predetermined feeding direction, the carrier tape including a base tape provided with a cavity configured to accommodate a component and a cover tape that is bonded to the base tape with two adhesive sections extending in a tape length direction and covers the cavity; a tape feeding mechanism configured to feed the carrier tape in the feeding direction along the tape guide and return the carrier tape in a reverse direction; a tape peeling mechanism configured to peel first side edge of the cover tape from the base tape together with one of the adhesive sections to open the cavity when the carrier tape is fed in the feeding direction; and a chamfered portion that is provided at an end portion on a downstream side of a lower surface of a ceiling plate located on an upstream side of the tape peeling mechanism in the feeding direction and constituting the tape guide, and extends in a width direction intersecting the feeding direction.

### Advantageous Effects

In the disclosed tape feeder including the first passage and the second passage, the second passage has the passage width dimension equal to or larger than the passage width dimension of the first passage. Therefore, the second passage can reduce stress acting when the peeled first side edge of the cover tape is returned in the reverse direction, and as a result, damage to the cover tape is reduced. Further, in the disclosed tape feeder including the chamfered portion, the chamfered portion can cause the cover tape returned in the reverse direction to smoothly pass therethrough. Therefore, the chamfered portion can reduce stress acting on the cover tape, and as a result, damage to the cover tape is reduced.

### BRIEF DESCRIPTION OF DRAWINGS

FIG. 1 is a perspective view illustrating a configuration example of a component mounter and a component mounting system to which a tape feeder of a first embodiment is applied.

FIG. 2 is a side view of the tape feeder of the first embodiment.

FIG. 3 is a cross-sectional view in a tape width direction illustrating a configuration of a carrier tape used by the tape feeder.

FIG. 4 is a plan view schematically illustrating a configuration of a tape guide and a tape peeling mechanism and illustrating a peeling operation.

FIG. 5 is a plan view illustrating only the carrier tape in FIG. 4.

FIG. 6 is a perspective view schematically illustrating a detailed configuration of a tape guide and a cover tape fed in a feeding direction.

FIG. 7 is a cross-sectional view of an X-Z cross section passing through the notch portion illustrated in FIG. 6 as viewed from a downstream side in a Y-axis direction.

FIG. 8 is a perspective view schematically illustrating a detailed configuration of the tape guide and the cover tape returned in a reverse direction.

FIG. 9 is a cross-sectional view of the X-Z cross section passing through the notch portion illustrated in FIG. 8 as viewed from the downstream side in the Y-axis direction.

FIG. 10 is a cross-sectional view of a configuration of a comparative example in which a notch portion is not provided and the carrier tape returned in the reverse direction as viewed from the downstream side in the Y-axis direction.

FIG. 11 is a perspective view schematically illustrating a chamfered portion provided in the tape guide and a peeling blade in a second embodiment.

FIG. 12 is a side cross-sectional view illustrating a cross-sectional shape of the chamfered portion and an action thereof.

FIG. 13 is a side cross-sectional view schematically illustrating a configuration of a comparative example including no chamfered portion and the carrier tape returned in the reverse direction.

FIG. 14 is a side cross-sectional view illustrating an action when the cover tape is fed in the feeding direction again from a state illustrated in FIG. 13.

FIG. 15 is a side view schematically illustrating an overall configuration of a tape feeder of a third embodiment.

### DESCRIPTION OF EMBODIMENTS

### 1. Configuration Example of Component Mounter 93 and Component Mounting System 9

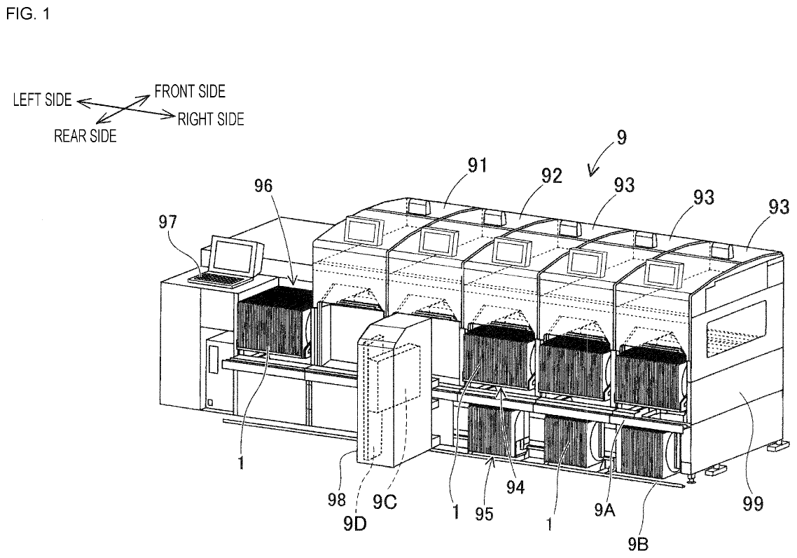

First, component mounter 93 to which tape feeder 1 of a first embodiment is applied and a configuration example of component mounting system 9 including component mounter 93 will be described with reference to FIG. 1. As illustrated in an upper left portion of FIG. 1, front, rear, left, and right of component mounting system 9 are defined for convenience. Component mounting system 9 includes multiple board work machine arranged in a left-right direction. That is, solder printer 91, printing inspector 92, three component mounters 93, a board visual inspector (not shown), and a reflow machine (not shown) are disposed side by side in the left-right direction. Each of the board work machines performs predetermined work on a board.

Three component mounters 93 have the same structure. Component mounter 93 includes component supply section 94, spare feeder storage section 95, a board conveyance device that is not illustrated in FIG. 1, and a component transfer device. Component supply section 94 is disposed at a substantially intermediate height on a rear side of machine base 99, and multiple tape feeders 1 are detachably arranged and equipped therein. Spare feeder storage section 95 is disposed below component supply section 94 on the rear side of machine base 99, and multiple tape feeders 1 for exchanging are detachably arranged and held therein. The board conveyance device carries in, positions, and carries out the board. The component transfer device picks up the component from tape feeder 1 of component supply section 94 using a component mounting tool, such as a suction nozzle, and mounts the component on the board.

Component mounting system 9 is provided with feeder storage device 96, line management device 97, and feeder exchanging device 98. Feeder storage device 96 is disposed adjacent to a left side of solder printer 91 and at the same height as component supply section 94 of component mounter 93. Also in feeder storage device 96, tape feeders 1 ready for use and used tape feeders 1 are arranged and stored. Line management device 97 is disposed adjacent to a left side of feeder storage device 96. Line management device 97 manages operation statuses of the multiple board work machines that are communicably connected.

Feeder exchanging device 98 conveys and exchanges tape feeder 1 at three locations of component supply section 94, spare feeder storage section 95, and feeder storage device 96 of component mounter 93. Feeder exchanging device 98 includes exchange section 9C that performs an exchanging operation and accommodation of tape feeder 1, and lifting and lowering drive section 9D that lifts and lowers exchange section 9C. Feeder exchanging device 98 travels along middle rail 9A and lower rail 9B provided on a rear surface of each of the multiple board work machines and feeder storage device 96.

### 2. Overall Configuration of Tape Feeder 1 of First Embodiment

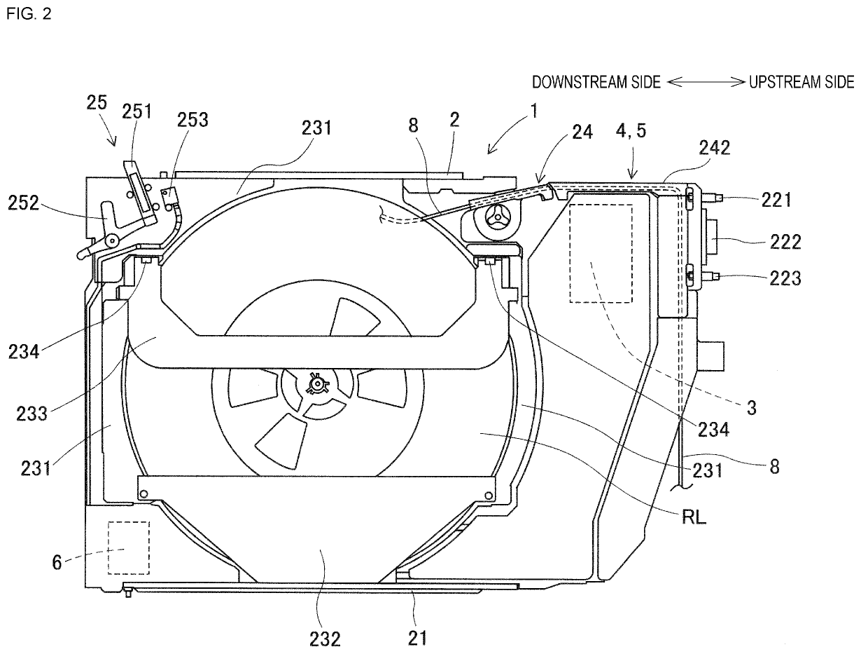

Next, an overall configuration of tape feeder 1 of the first embodiment will be described with reference to FIG. 2. A direction from a left side to a right side in FIG. 2 is a feeding direction of carrier tape 8, the left side is an upstream side, and the right side is a downstream side. Tape feeder 1 is formed to be thin in a width direction by assembling various members to feeder main body 2 including a side plate. Tape feeder 1 includes feeder main body 2, tape feeding mechanism 3, tape peeling mechanism 4, tape guide 5, feeder control section 6, and the like.

Feeder main body 2 includes detachable rail 21, reel accommodation frame 231, accommodation plate 232, opening/closing plate 233, tape conveyance path 24, and lock mechanism 25. Detachable rail 21 is provided on a bottom surface of feeder main body 2 and is used for attachment to component mounter 93. Upper positioning pin 221, connector 222, and lower positioning pin 223 are provided in this order from an upper side to a lower side of a downstream end surface of feeder main body 2. Upper positioning pin 221 and lower positioning pin 223 are inserted into positioning holes provided on a main body side of component mounter 93 to position tape feeder 1. When tape feeder 1 is positioned, connector 222 is automatically fitted to a receiving connector provided in component mounter 93. Accordingly, power is supplied to tape feeder 1, and feeder control section 6 is communicatively connected to the main body side of component mounter 93.

Reel accommodation frame 231 is multiple frame members that form a large circular internal space substantially at the center of feeder main body 2. Reel accommodation frame 231 rotatably accommodates reel RL in the internal space. Accommodation plate 232 is attached to a lower portion of reel accommodation frame 231. A separation distance between accommodation plate 232 and a side plate of feeder main body 2 is set to be slightly larger than a thickness of reel RL. Accommodation plate 232 prevents accommodated reel RL from being detached. Opening/closing plate 233 is attached above an intermediate height of reel accommodation frame 231. A separation distance between opening/closing plate 233 and the side plate of feeder main body 2 is set to be slightly larger than the thickness of reel RL. In addition, opening/closing plate 233 is opened and closed while support portions 234 at two positions in front and rear sides of an upper portion are swingably supported by feeder main body 2. Reel RL can be exchanged by opening/closing plate 233. Carrier tape 8 accommodating multiple components is wound around reel RL.

Tape conveyance path 24 forms a movement passage for feeding carrier tape 8 in a predetermined feeding direction. Tape conveyance path 24 may be formed in a rectangular tubular shape using, for example, a bottom plate, two side plates, and a ceiling plate, and a part of the tubular shape may be omitted. Tape conveyance path 24 extends obliquely upward in a downstream direction with a position close to reel RL as a start point, extends substantially horizontally in the downstream direction from the middle, and has an upper portion of feeder main body 2 at a downstream end as an end point. A position close to the end point of tape conveyance path 24 is a predetermined component supply position 242.

Tape peeling mechanism 4 is provided on an upstream side of tape conveyance path 24 with respect to component supply position 242. Tape conveyance path 24 guides carrier tape 8 pulled out from reel RL to tape peeling mechanism 4, and guides at least base tape 82 (described later) from tape peeling mechanism 4 to component supply position 242. Tape guide 5 is disposed close to tape peeling mechanism 4. Tape peeling mechanism 4 and tape guide 5 will be described in detail later.

Lock mechanism 25 is disposed at an upper portion of feeder main body 2 on the upstream side. Lock mechanism 25 includes lock pin 251, a lock operation member 252, and lock sensor 253. Lock pin 251 is a tubular member and is held by feeder main body 2 to be vertically movable. Lock pin 251 is brought into a locked state in a normal time by being pushed up by a biasing spring whose reference numeral is omitted, and restricts an operation of detaching tape feeder 1 from component supply section 94. Lock operation member 252 is a Y-shaped member having a swing fulcrum at the center. When lock operation member 252 is driven to swing automatically or manually, lock pin 251 is driven downward to release the locked state, and an operation of detaching tape feeder 1 from component supply section 94 is enabled. Lock sensor 253 detects a position of lock pin 251, that is, whether lock pin 251 is in the locked state, and outputs the result to feeder control section 6.

Tape feeding mechanism 3 feeds carrier tape 8 by a constant pitch and sequentially supplies the components at component supply position 242. Tape feeding mechanism 3 includes a sprocket, a servo motor, a gear mechanism, and the like (none of which are illustrated). The sprocket is disposed below tape conveyance path 24 and is rotatably supported by feeder main body 2. Teeth of the sprocket protrude from a groove formed in the bottom plate of tape conveyance path 24 and are fitted into feed holes 84 (described later) of carrier tape 8. The sprocket is driven by the servo motor and the gear mechanism, and can be switched between forward rotation and reverse rotation.

Feeder control section 6 is disposed at a lower portion of feeder main body 2 on the upstream side, and the position thereof is not limited. Feeder control section 6 is communicably connected to a control device on the main body side of component mounter 93 via connector 222. Feeder control section 6 controls tape feeding mechanism 3 and monitors a state of lock mechanism 25.

### 3. Configuration of Carrier Tape 8

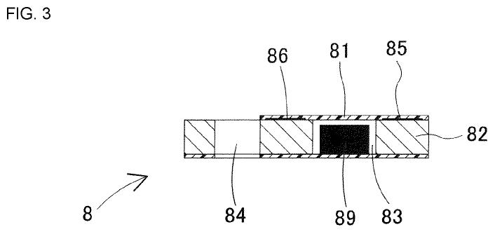

Next, a configuration of carrier tape 8 used in tape feeder 1 of the first embodiment will be described with reference to FIG. 3. Carrier tape 8 includes cover tape 81 and base tape 82. Base tape 82 is formed by forming multiple cavities 83 in a paper tape having a substantially constant thickness and attaching a thin film tape to a bottom surface. Additionally, a large number of rectangle hole-shaped cavities 83 are provided at equal pitches in a tape length direction at a position closer to a first side edge with respect to the center of base tape 82 in a tape width direction. Component 89 is accommodated in each of cavities 83. A large number of feed holes 84 are provided at equal pitches in the tape length direction at positions closer to a second side edge of base tape 82.

Cover tape 81 made of a thin film is peelably bonded to an upper surface of base tape 82. Cover tape 81 is formed using a transparent film so that component 89 inside cavity 83 can be checked visually or checked by an optical camera. First adhesive section 85 extending in the tape length direction is provided between cavity 83 of base tape 82 and the first side edge. Further, second adhesive section 86 extending in the tape length direction is provided between cavity 83 and feed hole 84 of base tape 82.

That is, the two adhesive sections (85 and 86) are arranged with multiple cavities 83 interposed therebetween. The two adhesive sections (85 and 86) peelably adhere two side edges of cover tape 81 to base tape 82. Note that each of the two adhesive sections (85 and 86) is not limited to a linear shape, and may be arranged intermittently as indicated by a broken line, for example. Cover tape 81 has a tape width dimension smaller than that of base tape 82 and covers cavity 83 but does not cover feed hole 84. There are multiple types of carrier tapes 8 having different tape width dimensions and tape thickness dimensions, and carrier tapes 8 correspond to various sizes of component 89.

There is an embossed carrier tape (not illustrated) having a structure different from that of paper carrier tape 8 described above. Similarly to carrier tape 8, the embossed carrier tape includes a cover tape and a base tape. However, the base tape constituting the embossed carrier tape is subjected to an expansion process at equal pitches in a tape length direction of a resin tape to form cavities. The embossed carrier tape has compatibility in use with paper carrier tape 8.

### 4. Configurations of Tape Guide 5 and Tape Peeling Mechanism 4 and Peeling Operation

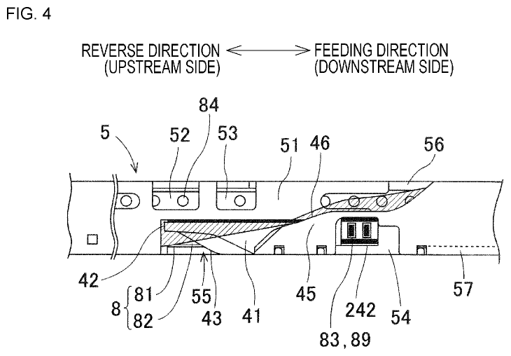

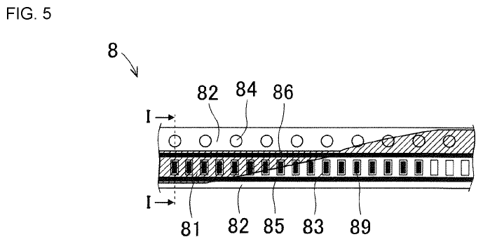

Next, configurations of tape guide 5 and tape peeling mechanism 4 and a peeling operation will be described with reference to FIGS. 4 and 5. In FIGS. 4 and 5, cover tape 81 constituting carrier tape 8 is illustrated with diagonal hatching for convenience. The two adhesive sections (85 and 86) and component 89 are illustrated in black for convenience.

Tape guide 5 is detachably provided on feeder main body 2. Tape guide 5 is a part of tape conveyance path 24 that guides carrier tape 8 in the predetermined feeding direction. As illustrated in FIG. 4, tape guide 5 includes first ceiling plate 51, second ceiling plate 54, side plate 56, and side plate 57. Side plate 56 and side plate 57 are separated from each other and extend in parallel to the feeding direction of carrier tape 8. Side plate 56 and side plate 57 may be located at least on the downstream side of first ceiling plate 51 and may extend longer in the feeding direction.

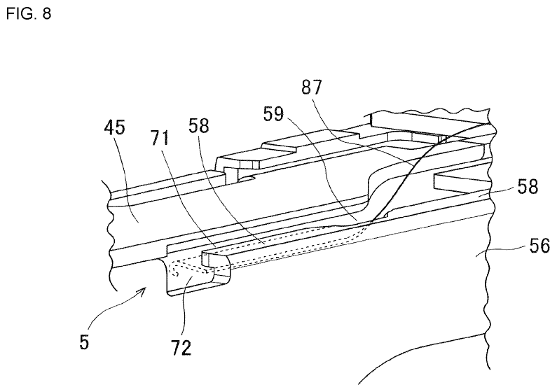

First ceiling plate 51 and second ceiling plate 54 are flat plate-shaped members, and are arranged in parallel while being separated from bottom plate 455 (see FIG. 8) of tape conveyance path 24. A separation dimension between bottom plate 455 and each of first ceiling plate 51 and second ceiling plate 54 is slightly larger than a thickness dimension of carrier tape 8. Carrier tape 8 moves in a movement passage formed by the separation dimension. An upstream portion of first ceiling plate 51 occupies substantially an entire width of feeder main body 2. A downstream portion of first ceiling plate 51 has a reduced width dimension and is disposed closer to first side plate 56. First ceiling plate 51 is formed with notch windows (52 and 53) that make feed holes 84 of carrier tape 8 visible.

First ceiling plate 51 is biased downward by a biasing spring (not illustrated). and presses carrier tape 8 against bottom plate 455. Accordingly, teeth of second sprocket 32 are reliably fitted into feed holes 84 of carrier tape 8, and a relative height of carrier tape & with respect to tape peeling mechanism 4 is stabilized. Second ceiling plate 54 is disposed closer to second side plate 57 on the downstream side with respect to first ceiling plate 51. Second ceiling plate 54 is opened by notching a portion corresponding to component supply position 242. Opening section 55 extending in the feeding direction is formed between first ceiling plate 51 and second ceiling plate 54.

As illustrated in FIG. 4, tape peeling mechanism 4 includes peeling blade 41 and tape folding-back member 45. Peeling blade 41 is disposed closer to second side plate 57 in opening section 55 upstream of second ceiling plate 54. Peeling blade 41 has distal end portion 42 and blade edge 43. Distal end portion 42 is located at an upstream end of peeling blade 41 and faces the upstream side. Since distal end portion 42 is formed to be thin in an up-down direction, distal end portion 42 can easily enter between base tape 82 and cover tape 81.

Blade edge 43 is disposed on one side of distal end portion 42 in the tape width direction, and overlaps first adhesive section 85 of fed carrier tape 8 but does not overlap second adhesive section 86. Blade edge 43 is formed to extend obliquely with respect to the feeding direction, and is formed to be thin in the up-down direction, so that first adhesive section 85 can be easily peeled off. A height position of peeling blade 41 can be adjusted, and heights of distal end portion 42 and blade edge 43 with respect to carrier tape 8 are optimized.

Tape folding-back member 45 is formed to be continuous with a downstream side of peeling blade 41. Tape folding-back member 45 is disposed above and in parallel to second ceiling plate 54. Tape folding-back member 45 is gradually widened in the downstream direction away from peeling blade 41. Tape folding-back member 45 includes side edge 46 for folding back cover tape 81 to open cavity 83 at a widened portion. A downstream portion of tape folding-back member 45 occupies substantially the entire width of feeder main body 2. Tape folding-back member 45 is opened by notching the portion corresponding to component supply position 242.

Next, the peeling operation of tape peeling mechanism 4 will be described. When carrier tape 8 is fed, tape peeling mechanism 4 peels first side edge 87 of cover tape 81 from base tape 82 together with first adhesive section 85 to open cavity 83. Specifically, when tape feeding mechanism 3 operates and carrier tape 8 is fed in the feeding direction, the tip end of carrier tape 8 and peeling blade 41 face each other. When carrier tape 8 is further fed and the tip end thereof reaches peeling blade 41, distal end portion 42 first enters between base tape 82 and. cover tape 81. When carrier tape 8 is further fed, distal end portion 42 relatively advances between base tape 82 and cover tape 81. Further, blade edge 43 obliquely comes into contact with advancing adhesive section 85 to cut and open adhesive section 85, and peels off cover tape 81 from base tape 82. Accordingly, cover tape 81 is fed in the downstream direction in a half-peeled state in which first adhesive section 85 and first side edge 87 are peeled off and second adhesive sections 86 and a second side edge are bonded.

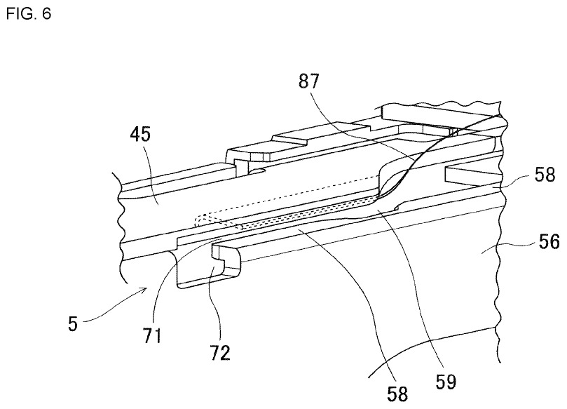

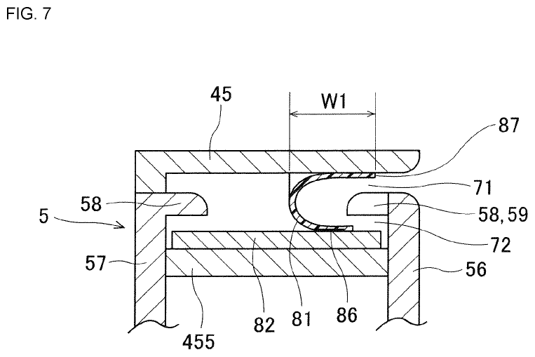

As shown in FIG. 4, half-peeled cover tape 81 passes above peeling blade 41. As cover tape 81 is fed in the downstream direction, cover tape 81 rises above second adhesive section 86 along a side surface of peeling blade 41. Further, cover tape 81 is folded back in a direction toward first side plate 56 alongside edge 46 of tape folding-back member 45. Thereafter, as illustrated in FIGS. 6 and 7, cover tape 81 is in a folded-back state that is rotated by 180° from component supply position 242. Accordingly, cavity 83 is opened, and component 89 can be supplied. After component 89 is taken out, carrier tape 8 is fed in the downstream direction in a state in which cover tape 81 is adhered to base tape 82 by second adhesive section 86.

As illustrated in FIG. 2, carrier tape 8 that has passed component supply position 242 is bent substantially by 90° downward at a downstream end of tape conveyance path 24, is discharged to an outside, and is sent to an inside of component mounter 93. Component mounter 93 is provided with a tape cutter and a retrieval box (not illustrated). The tape cutter operates at a predetermined operation timing to cut carrier tape 8. Carrier tape 8 that has been cut falls toward the retrieval box. When carrier tape 8 is bent, folded cover tape 81 is strongly pressed in a direction toward base tape 82 and is given a bending tendency.

Here, it is assumed that tape feeder 1 is detached from component mounter 93 by the exchanging operation performed by feeder exchanging device 98. In this case, when tape feeder 1 is removed in an operating state, carrier tape 8 fed to the outside is in an exposed state. Exposed carrier tape 8 may hinder the exchanging operation of feeder exchanging device 98. Therefore, when tape feeder I is removed, feeder control section 6 causes tape feeding mechanism 3 in advance to return carrier tape 8 in a reverse direction and store carrier tape 8 inside tape feeder 1.

As another case where carrier tape 8 is returned in the reverse direction, there is a case where the peeling of the tip end of carrier tape 8 fails and a recovery operation is performed. In addition, there may be a case where tape feeder I temporarily stops because of a power failure or the like, and a position of carrier tape 8 in the feeding direction, a position of leading cavity 83 accommodating component 89 for example, becomes unknown. In this case, feeder control section 6 returns and feeds carrier tape 8 and checks the position thereof.

### 5. Detailed Configuration and Action of Tape Guide 5

Next, the detailed configuration and an action of tape guide 5 will be described with reference to FIGS. 6 to 9. As illustrated, tape guide 5 is provided with first passage 71 and second passage 72. More specifically, inward bent portions 58 are provided on the side plates (56 and 57) of tape guide 5. Inward bent portion 58 is formed by bending upper portions of the side plates (56 and 57) inward in the passage width direction. Inward bent portion 58 is provided for the purpose of increasing the rigidity (mechanical strength) of tape guide 5 or stabilizing the attachment position or attachment posture of tape guide 5. Inward bent portion 58 is located below tape folding-back member 45 and is parallel to tape folding-back member 45.

Notch portion 59 is provided at an intermediate position of inward bent portion 58 of first side plate 56 in the feeding direction. Notch portion 59 is preferably notched over an entire length of a width dimension of inward bent portion 58. First passage 71 is located above inward bent portion 58 and between inward bent portion 58 and tape folding-back member 45. First passage 71 serves as a movement passage when peeled first side edge 87 of cover tape 81 is fed in the feeding direction.

Meanwhile, second passage 72 is located below first passage 71 and below inward bent portion 58. Second passage 72 serves as a movement passage when first side edge 87 of cover tape 81 is returned in the reverse direction. Notch portion 59 enables cover tape 81 returned in the reverse direction to return in the reverse direction from the lower side to the upper side and is included in a part of second passage 72. The omission of inward bent portion 58 to expand the movement passage of cover tape 81 is not allowed because the rigidity or attachment stability of tape guide 5 is reduced.

As shown in FIGS. 6 and 7, when carrier tape 8 is fed in the feeding direction, first side edge 87 of cover tape 81 is fed in the downstream direction from the upstream side through first passage 71. In this case, first side edge 87 is fed while being pressed against the lower surface of tape folding-back member 45 by an action of the original elasticity of cover tape 81.

As described above, cover tape 81 is bent at the downstream end of tape conveyance path 24 so that cover tape 81 is given a bending tendency in which first side edge 87 comes into contact with base tape 82 or is close to base tape 82. Because of an action of the bending tendency, the movement passage of first side edge 87 of cover tape 81 when carrier tape 8 is returned in the reverse direction changes from first passage 71 to second passage 72. However, on the upstream side of tape peeling mechanism 4, peeled cover tape 81 is returned in a state of being in contact with the two adhesive sections (85 and 86) as before the peeling.

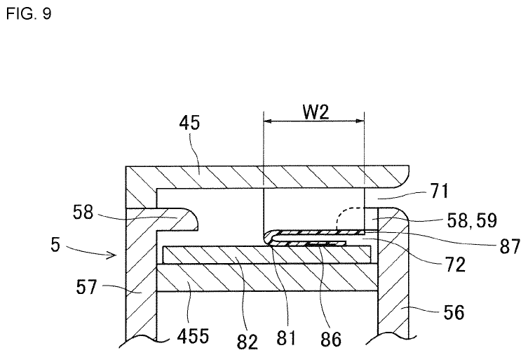

As shown in FIGS. 8 and 9, when carrier tape 8 is returned in the reverse direction, first side edge 87 of cover tape 81 is pulled downward by the action of the bending tendency, and slides down from first passage 71 to second passage 72 through an inside of inward bent portion 58. Thereafter, first side edge 87 is returned to notch portion 59 through second passage 72 from the downstream side. Further, first side edge 87 is returned in an upstream direction through notch portion 59 from the lower side to the upper side.

As shown in FIG. 7, the substantial passage width dimension of first passage 71 through which first side edge 87 of cover tape 81 passes is WI corresponding to the width dimension of a folded portion including first side edge 87 of cover tape 81. Meanwhile, in FIG. 9, the substantial passage width dimension of second passage 72 through which first side edge 87 of cover tape 81 passes is W2 corresponding to the width dimension of the folded portion including first side edge 87 of cover tape 81. By providing notch portion 59 that is a part of second passage 72, passage width dimension W2 of second passage 72 can enter notch portion 59. According to this, passage width dimension W2 of second passage 72 can be equal to or larger than passage width dimension WI of first passage 71.

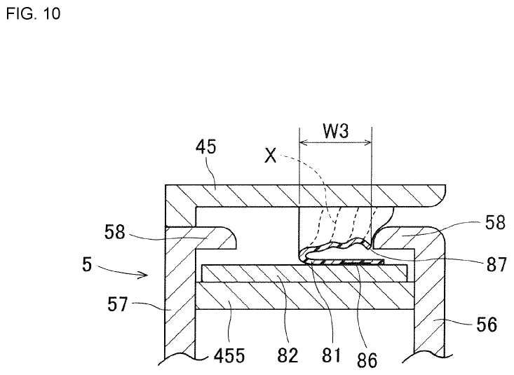

In contrast, in a configuration of a comparative example illustrated in FIG. 10 in which notch portion 59 is not provided, first side edge 87 of cover tape 81 cannot return in the upstream direction through notch portion 59. Therefore, first side edge 87 is returned in the upstream direction from second passage 72 on the downstream side through the inside of inward bent portion 58. In the configuration of the comparative example, substantial passage width dimension W3 of the movement passage through which first side edge 87 of cover tape 81 passes is restricted by an inner end of inward bent portion 58, and thus is narrower than passage width dimension W2. Therefore, cover tape 81 is subjected to excessive stress that is compressed in the tape width direction, and wrinkles X, irregular slack, and the like are likely to occur. Meanwhile, according to the first embodiment, since second passage 72 is not narrowed, it is possible to reduce the stress acting on cover tape 81 from tape guide 5 when first side edge 87 is returned in the reverse direction.

In tape feeder 1 of the first embodiment, second passage 72 including notch portion 59 includes passage width dimension W2 equal to or larger than that of first passage 71. Therefore, second passage 72 can reduce the stress acting from tape guide 5 when peeled first side edge 87 of cover tape 81 is returned in the reverse direction. As a result, damage to cover tape 81 such as wrinkles X and irregular slack is suppressed. Accordingly, it is possible to improve the reliability of the component supply of tape feeder 1 and to contribute to high production efficiency of component mounter 93. For example, a tape feeding error in tape feeder 1 and a component collection error in component mounter 93 are reduced, and an occurrence frequency of the temporary production stop of component mounter 93 is reduced.

### 6. Tape Feeder 1 of Second Embodiment

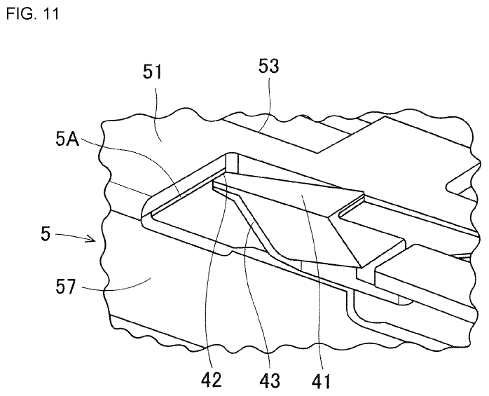

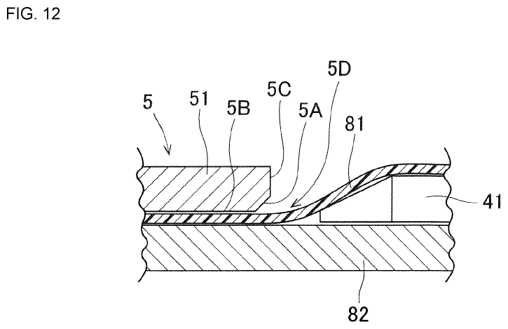

Next, tape feeder 1 of a second embodiment will be described with reference to FIGS. 11 and 12. As illustrated, in the second embodiment, chamfered portion 5A is provided on first ceiling plate 51 of tape guide 5. Chamfered portion 5A is provided at a downstream end portion of lower surface 5B of first ceiling plate 51 and is located slightly upstream of tape peeling mechanism 4 in the feeding direction. Therefore, chamfered portion 5A faces peeling blade 41 from the upstream side in the feeding direction. Chamfered portion 5A extends in the width direction intersecting the feeding direction.

Chamfered portion 5A illustrated in FIG. 12 is formed by an inclined flat surface inclined by approximately 45″ with respect to lower surface 5B and downstream end surface 5C of first ceiling plate 51. Chamfered portion 5A is not limited thereto, and may be formed by multiple inclined flat surfaces that have different inclination angles and are continuous. Chamfered portion 5A may be formed by a smooth curved surface including a part of a cylindrical surface.

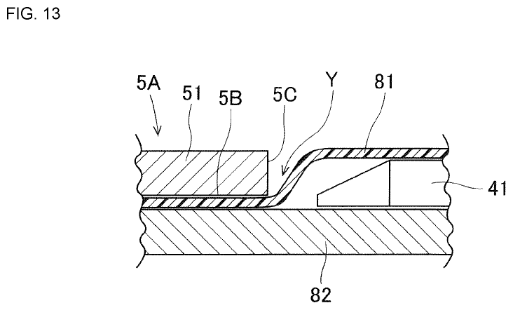

Here, space region 5D through which cover tape 81 can pass is formed between first ceiling plate 51 and peeling blade 41. Chamfered portion 5A expands space region 5D as compared with the configuration of the comparative example that does not include chamfered portion 5A, the configuration being illustrated in FIG. 13. Further, chamfered portion 5A relaxes the edge of first ceiling plate 51 on the downstream side to prevent returned cover tape 81 from being caught. That is, chamfered portion 5A is configured to facilitate the passage of returned cover tape 81. Accordingly, as illustrated in FIG. 12, returned cover tape 81 is smoothly returned from the upper side of peeling blade 41 to the lower side of first ceiling plate 51. Thereafter, when carrier tape 8 is fed in the feeding direction again, cover tape 81 is smoothly fed.

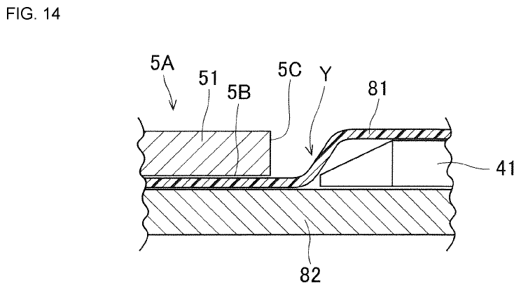

In contrast, in the configuration of the comparative example shown in FIG. 13, unlike the second embodiment, the space region of first ceiling plate 51 on the downstream side is narrow, and there is a substantially right-angled edge on the downstream side of first ceiling plate 51. Therefore, returned cover tape 81 tends to stay near downstream end surface 5C of first ceiling plate 51. As a result, irregular slack Y is likely to occur in cover tape 81. Thereafter, as illustrated in FIG. 14, when carrier tape 8 is fed in the feeding direction again, a concern that peeling blade 41 sticks into slack Y of cover tape 81 increases. Therefore, cover tape 81 is subjected to excessive stress from peeling blade 41, and damage such as tearing is likely to occur. On the other hand, according to the second embodiment, chamfered portion 5A relaxes the edge while expanding space region 5D, and cover tape 81 returned in the reverse direction can smoothly pass therethrough. Therefore, chamfered portion 5A can reduce the stress acting on cover tape 81 from tape guide 5. As a result, damage such as slack Y and the tearing of cover tape 81 is suppressed.

### 7. Overall Configuration of Tape Feeder 1A of Third Embodiment

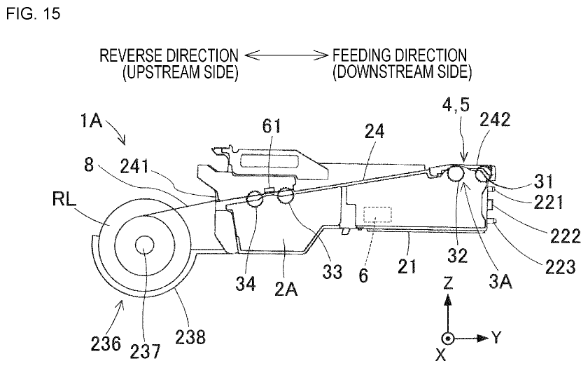

Next, an overall configuration of tape feeder LA of a third embodiment will be described with reference to FIG. 15. As indicated by a lower right arrow in FIG. 15, an X-axis direction and a Y-axis direction in a horizontal plane and a Z-axis direction corresponding to a vertical direction are defined for convenience. The X-axis direction coincides with a direction in which the board is conveyed in a component mounter equipped with tape feeder 1A. The Y-axis direction coincides with the predetermined feeding direction in which carrier tape 8 is fed. The direction from the left side to the right side in FIG. 15 is the feeding direction, the left side is the upstream side, and the right side is the downstream side. The overall configuration of tape feeder 1A of the third embodiment is different from that of the first and second embodiments. Tape feeder 1A includes feeder main body 2A, tape feeding mechanism 3A (partly not illustrated), tape peeling mechanism 4, tape guide 5, feeder control section 6, and the like.

Feeder main body 2A is formed using one side plate long in the Y-axis direction as a main material. A width dimension of feeder main body 2A in the X-axis direction is determined in accordance with tape width dimensions of multiple types of carrier tapes 8. That is, there are multiple types of tape feeders 1A having different width dimensions. Feeder main body 2A includes detachable rail 21, reel holding section 236, and tape conveyance path 24. Detachable rail 21 is provided on a downstream side of a bottom surface of feeder main body 2A and extends in the Y-axis direction. Detachable rail 21 is used for attachment to the component mounter.

Upper positioning pin 221, connector 222, and lower positioning pin 223 are provided in this order from an upper side to a lower side of a downstream end surface of feeder main body 2A. Upper positioning pin 221 and lower positioning pin 223 are inserted into positioning holes provided on a main body side of the component mounter to position tape feeder 1A. When tape feeder 1A is positioned, connector 222 is automatically fitted to a receiving connector provided in the component mounter. Accordingly, power is supplied to tape feeder IA, and feeder control section 6 is communicatively connected to the main body side of the component mounter.

Reel holding section 236 is provided at an upstream lower portion of feeder main body 2. Reel holding section 236 holds reel RL around which carrier tape 8 is wound in an exchangeable manner. Reel holding section 236 is formed by at least one of holding shaft 237 and outer peripheral holding section 238. Holding shaft 237 is disposed to extend in the X-axis direction and rotatably holds a center hole of reel RL. Outer peripheral holding section 238 rotatably holds an outer peripheral edge of reel RL.

Tape conveyance path 24 forms a movement passage for feeding carrier tape 8 in a predetermined feeding direction. Tape conveyance path 24 may be formed in a rectangular tubular shape using, for example, a bottom plate, two side plates, and a ceiling plate, and a part of the tubular shape may be omitted. Tape conveyance path 24 extends obliquely upward in a downstream direction with insertion port 241 close to reel holding section 23 as a start point, extends substantially horizontally in the downstream direction from the middle, and has an upper portion of feeder main body 2 at a downstream end as an end point. A position close to the end point of tape conveyance path 24 is a predetermined component supply position 242.

Tape peeling mechanism 4 is provided on an upstream side of tape conveyance path 24 with respect to component supply position 242. Tape conveyance path 24 guides carrier tape 8 pulled out from reel RL to tape peeling mechanism 4, and guides at least base tape 82 from tape peeling mechanism 4 to component supply position 242. Tape guide 5 is disposed close to tape peeling mechanism 4. Tape peeling mechanism 4 and tape guide 5 have the same configurations as those of the first and second embodiments.

Tape feeding mechanism 3A feeds carrier tape 8 by a constant pitch and sequentially supplies components 89 at component supply position 242. Tape feeding mechanism 3A includes four sprockets, two groups of a servo motor and a gear mechanism (not illustrated), and the like. First sprocket 31 is disposed below a position slightly downstream of component supply position 242 of tape conveyance path 24 and is rotatably supported by feeder main body 2. Second sprocket 32 is disposed below a position slightly upstream of tape peeling mechanism 4 of tape conveyance path 24 and is rotatably supported by feeder main body 2. Teeth of each of first sprocket 31 and second sprocket 32 protrude from a groove formed in the bottom plate of tape conveyance path 24 and are fitted into feed holes 84 of carrier tape 8. First sprocket 31 and second sprocket 32 are synchronously driven by the front servo motor and the front gear mechanism, and can be switched between forward rotation and reverse rotation.

Third sprocket 33 and fourth sprocket 34 are disposed below tape conveyance path 24 slightly downstream of insertion port 241, and are rotatably supported by feeder main body 2. Teeth of each of third sprocket 33 and fourth sprocket 34 protrude from a groove formed in the bottom plate of tape conveyance path 24 and are fitted into feed holes 84 of carrier tape 8. Third sprocket 33 and fourth sprocket 34 are synchronously driven by the rear servo motor and the rear gear mechanism, and can be switched between forward rotation and reverse rotation.

During normal operation, the four sprockets rotate forward in synchronization with each other to feed carrier tape 8 in the feeding direction by a constant pitch. In a loading operation at the start of use of carrier tape 8, third sprocket 33 and fourth sprocket 34 rotate forward first, and then first sprocket 31 and second sprocket 32 rotate forward. The loading operation means that the tip end of carrier tape 8 to be used is loaded to component supply position 242 and setup is performed in an operable state. In addition, when carrier tape 8 that is being used in one stage of operation is removed, the four sprockets are rotated in reverse in synchronization with each other to feed carrier tape 8 in the reverse direction of the feeding direction. The number of sprockets may be three or less.

Feeder control section 6 is provided in feeder main body 2A, and the position thereof is not limited. Feeder control section 6 is a computer device operated by software. Feeder control section 6 controls the front servo motor and the rear servo motor. Feeder control section 6 is communicatively connected to a control section of the component mounter by connector 222, and receives a command. Feeder control section 6 is connected to tape detection sensor 61. Tape detection sensor 61 is disposed in an inclined portion between third sprocket 33 and fourth sprocket 34 of tape conveyance path 24, and detects the presence or absence of carrier tape 8 to be fed. Feeder control section 6 receives a detection signal from tape detection sensor 61 and reflects the detection signal in control of feeding and returning of carrier tape 8. The number and positions of tape detection sensors 61 may be different from those described above. In tape feeder 1A, carrier tape 8 may be fed from reel RL held in a separate reel holding device without holding reel RL held in feeder main body 2.

In the third embodiment, notch portion 59 is provided at an intermediate position of inward bent portion 58 of one of side plates 56 of tape guide 5 in the feeding direction. According to this, in the third embodiment, the same actions and effects as those of the first embodiment are obtained. Further, in the third embodiment, chamfered portion 5A is provided on first ceiling plate 51 of tape guide 5. According to this, in the third embodiment, the same actions and effects as those of the second embodiment are obtained. That is, by providing notch portion 59 and chamfered portion 5A in tape guide 5 of one tape feeder 1A, the effect of reducing damage to cover tape 81 is ensured.

### 8. Application and Modification of Embodiment

The configuration of the first embodiment may be construed as tape feeder 1 that includes feeder main body 2 including tape feeding mechanism 3 and tape peeling mechanism 4, and tape guide 5 including first passage 71, second passage 72, inward bent portion 58, and notch portion 59, and detachably provided in feeder main body 2. The configuration of the second embodiment may be construed as tape feeder 1 that includes feeder main body 2 including tape feeding mechanism 3 and tape peeling mechanism 4, and tape guide 5 including first ceiling plate 51 and chamfered portion 5A, and detachably provided in feeder main body 2.

In addition, the tape feeders (1, 1A) of the first to third embodiments act on the embossed carrier tape in the same manner as paper carrier tape 8, and the same effects are obtained. Further, the tape feeders (1, 1A) may be an automatic loading feeder. By loading second carrier tape 8 to a standby position during use of first carrier tape 8, the automatic loading feeder can automatically start use of second carrier tape 8 after the end of use of first carrier tape 8. Various other applications and modifications can be made for the first to third embodiments.

### REFERENCE SIGNS LIST

1, 1A: tape feeder, 2, 2A: feeder main body, 24: tape conveyance path, 242: component supply position, 3, 3A: tape feeding mechanism, 4: tape peeling mechanism, 41: peeling blade, 45: tape folding-back member, 455: bottom plate, 5: tape guide, 51: first ceiling plate, 56, 57: side plate, 58: inward bent portion, 59: notch portion, 5A: chamfered portion, 5B: lower surface, 5D: space region, 6: feeder control section, 71: first passage, 72: second passage, 8: carrier tape, 81: cover tape, 82: base tape, 83: cavity, 85, 86: adhesive section, 87: first side edge, 89: component, 93: component mounter, W1, W2, W3: passage width dimension, X: wrinkle, Y: irregular slack

1. A tape feeder comprising:
a tape guide configured to guide a carrier tape in a predetermined feeding direction, the carrier tape including a base tape provided with a cavity configured to accommodate a component and a cover tape that is bonded to the base tape with two adhesive sections extending in a tape length direction and covers the cavity;
a tape feeding mechanism configured to feed the carrier tape in the feeding direction along the tape guide and return the carrier tape in a reverse direction;
a tape peeling mechanism configured to peel a first side edge of the cover tape from the base tape together with one of the adhesive sections to open the cavity when the carrier tape is fed in the feeding direction; and
a first passage that is provided in the tape guide and through which the peeled first side edge of the cover tape is fed in the feeding direction, and a second passage that is located below the first passage and has a passage width dimension equal to or larger than a passage width dimension of the first passage and through which the peeled first side edge of the cover tape is returned in the reverse direction.

2. The tape feeder according to claim 1, wherein
the first passage is located above an inward bent portion in which an upper portion of a side plate constituting the tape guide is bent inward in a passage width direction, and
the second passage is located below the inward bent portion.

3. The tape feeder according to claim 2, wherein the second passage includes a notch portion that is provided in the inward bent portion and enables the peeled first side edge of the cover tape to return in the reverse direction by passing through the notch portion from below to above.

4. The tape feeder according to claim 2,
wherein the tape peeling mechanism includes a tape folding-back member extending in the passage width direction and configured to fold back the peeled first side edge of the cover tape over a second side edge thereof, and
the first passage is located between the inward bent portion and the tape folding-back member.

5. A tape feeder comprising:
a tape guide configured to guide a carrier tape in a predetermined feeding direction, the carrier tape including a base tape provided with a cavity configured to accommodate a component and a cover tape that is bonded to the base tape with two adhesive sections extending in a tape length direction and covers the cavity;
a tape feeding mechanism configured to feed the carrier tape in the feeding direction along the tape guide and return the carrier tape in a reverse direction;
a tape peeling mechanism configured to peel a first side edge of the cover tape from the base tape together with one of the adhesive sections to open the cavity when the carrier tape is fed in the feeding direction; and
a chamfered portion that is provided at an end portion on a downstream side of a lower surface of a ceiling plate located on an upstream side of the tape peeling mechanism in the feeding direction and constituting the tape guide, and extends in a width direction intersecting the feeding direction.

6. The tape feeder according to claim 5, wherein
the tape peeling mechanism includes a peeling blade configured to enter one of the adhesive sections when the carrier tape is fed in the feeding direction, and
the chamfered portion faces the peeling blade from the upstream side in the feeding direction.

7. The tape feeder according to claim 6, wherein the chamfered portion expands a space region through which the cover tape passes between the ceiling plate and the peeling blade, as compared with a configuration that does not include the chamfered portion.

8. The tape feeder according to claim 5, wherein the ceiling plate presses the carrier tape against a bottom plate located below the tape guide.

9. The tape feeder according to claim 3, further comprising:
a feeder main body including the tape feeding mechanism and the tape peeling mechanism; and
the tape guide including the first passage, the second passage, the inward bent portion, and the notch portion, and detachably provided in the feeder main body.

10. The tape feeder according to claim 5, further comprising:
a feeder main body including the tape feeding mechanism and the tape peeling mechanism; and
the tape guide including the ceiling plate and the chamfered portion, and detachably provided in the feeder main body.

11. The tape feeder according to claim 1, wherein the tape feeding mechanism is configured to return the carrier tape fed out of the tape feeder in the reverse direction to accommodate the carrier tape inside the tape feeder when the tape feeder is removed from the component mounter.
